(19) United States
(12) Patent Application Publication
(10) Pub. No.: US 2004/0158782 A1
(43) Pub. Date: Aug. 12, 2004

(54) Method for protected transmission of data via an air interface

(75) Inventor: Michael Cuylen, Zirndorf (DE)

Correspondence Address: SUGHRUE MION, PLLC, 2100 PENNSYLVANIA AVENUE, N.W., SUITE 800, WASHINGTON, DC, 20037, US

(73) Assignee: SIEMENS AKTIENGESELLSCHAFT

(21) Appl. No.: 10/722,499

(22) Filed: Nov. 28, 2003

Related U.S. Application Data
(63) Continuation of application No. PCT/DE03/00858, filed on Mar. 17, 2003.

(30) Foreign Application Priority Data
Mar. 28, 2002 (DE) 102 141 88.6

(51) Int. Cl. G01R 31/28

(52) U.S. Cl. 714/712

(57) ABSTRACT

A method and associated structures for protected transmission of data (D0-D4), whose coding (“S”, “0”-“F”) is represented by a sequence (FR0-FR4) having a predetermined number of on and off values (Z1, Z0). Therein, a count (C), which represents the predetermined number, is formed by changing the counting direction (F, R) after each on-value and by incrementing or decrementing the count (C) for each off-value. An error information (F1, F2) is generated, if a first final value (EC), which is transmitted, together with the data, as a coded sequence (SIG) of the count (C), differs from a second final value (EC1, EC2). Like the count (C), the second final value (EC1, EC2) is formed from the transmitted sequence (SIG). The method can be used for identification systems (IS), for mobile data storage media (DT), and for readers/writers (SLG). A simple upward and downward counter (CNT) makes it possible to identify data transmission errors quickly and with a high degree of confidence. The counter (CNT) may be a simple software program or an electronic circuit, such as a binary cycle counter, which has low circuitry complexity.

This is a Continuation of International Application PCT/DE03/00858, with an international filing date of Mar. 17, 2003, which was published under PCT Article 21(2) in German, and the disclosure of which is incorporated into this application by reference.

### FIELD OF AND BACKGROUND OF THE INVENTION

The invention relates to a method for protected transmission of data, whose coding is represented by a sequence of a predetermined number of on and off values. The invention furthermore relates to a mobile data memory and to a reader/writer for carrying out the method, as well as to an identification system having the reader/writer and having at least one mobile data memory.

Non-contacting identification systems operate on the basis of non-contacting transmission techniques. For example, these non-contacting transmission techniques may be based on electromagnetic principles, such as infrared or ultrasound transmissions. Such systems are used, for example, for identifying personnel or moving goods, such as transportation means. Therein, the necessary data is transmitted from a reader/writer to a mobile data memory and back via a non-contacting data transmission path, for example, via an air interface. The non-contacting identification technique also allows for acquiring data when the mobile data memory moves by, for example. In order to use the mobile data memories for an unlimited time, no energy stores, such as batteries, are integrated in the mobile data memories. The electrical power is obtained externally in a non-contacting manner, that is from an electrical or magnetic field that originates from the reader/writer.

For a reader/writer to communicate with such mobile data memories, suitable transmission and coding methods are necessary, which ensure not only that the electronics in the mobile data memory are supplied with power, but also that radio requirements are complied with. Furthermore, in general, only specific frequency bands are allowed for transmitting data. For example, the ISM frequency bands (Industrial, Scientific & Medical) can be used for industrial, scientific and medical applications.

In accordance with, for example, ISO/IEC Standard 15693 Part 2 “Air Interface and Initialization” or ISO/IEC Standard 14443, these methods are known as time slot methods for operation in an ISM frequency band.

Methods of this type allow power to be continuously supplied to the data memory electronics. Therein, for the purpose of transmitting power, the carrier frequency, which is modulated with the data to be transmitted, is switched off only for a maximum time interval. Within this time interval, an energy store, which has previously been charged in the mobile data memory, needs to be able to bridge the power supply. Conversely, the data is transmitted from the mobile data memory to the reader/writer by means of loading modulation. In the process, the mobile data memory damps the inducing magnetic field in short intervals. In this loading phase, the mobile data memory requires the maximum power from the previously charged energy store. Thus, this loading phase should be as short as possible. In accordance with the above Standards, the loading modulation may be carried out continuously for one time slot as the maximum time interval. Alternatively, the loading modulation may be carried out by using carrier-frequency modulation via an auxiliary carrier. In the case of carrier-frequency modulation, power can also be transmitted within a modulated time slot (in this context, see also FIG. 3).

Data transmission between a reader/writer and a mobile data memory may, however, be disadvantageously influenced by interference. For example, in the case of data transmission on inductively coupled paths, interference may be caused by electromagnetic interference sources such as motors, solenoid valves, welding robots, etc., which are operated in the relatively close surrounding area. This can result in faulty data transmission.

Suitable protection methods are known for reducing this problem, such as determining and attaching a CRC word (Cycle Redundancy Check) or a parity bit to the end of the data or data sequence to be transmitted.

When a protected method is used based on adding a CRC word to a data sequence, the error identification probability in the event of a transmission error is very high. However, since the received first part of the data must be validated by the CRC word, a high degree of data processing computation complexity by the mobile data memory is necessary. Consequently, the current consumption for the extensive computation operations may become so great that it is no longer possible to supply power by means of external power transmission from the reader/writer. It is a further disadvantage that, due to the computation operations that are still going to be used for CRC validation, it may no longer be possible to process newly arriving data. This can disadvantageously result in data being lost during data transmission. It is another disadvantage that it may no longer be possible to interchange all of the data awaiting transmission while the mobile data memory is located in the reception area of the reader/writer.

On the other hand, when using a parity bit for protected transmission of data, the computational complexity is very low in comparison to determining a CRC word. However, the error identification probability for a data sequence that has been subjected to interference is not very high. If, for example, two time slots within a transmitted sequence have been subjected to interference during a data transmission such that they assume complementary values, then the value of the parity bit does not change. In addition, no transmission errors can be detected when, for example, due to insufficiently accurate synchronization between the reader/writer and the mobile data memory, the sampling of an incoming data stream in the time slot window is not “central”. It is thus possible, for example, that a current data transmission value is sampled only in the next time slot. This would result in a different logical result. In this situation too, the value of the parity bit would not change, indicating correct data transmission. Further, time offsets may be caused by reflections of the transmitted data on metal surfaces, for example.

### OBJECTS OF THE INVENTION

It is one object of the invention to provide a method for protected transmission of data, which has a high error identification probability of transmission interference and which allows for low data processing complexity.

### SUMMARY OF THE INVENTION

According to one formulation of the present invention, this and other objects are achieved by a method for protected transmission of data whose coding is represented by a first, transmitted sequence that has a predetermined number of on and off values. A count, which represents the predetermined number, is formed by changing a counting direction after each on-value and by incrementing or decrementing the count for each off-value. In addition, error information is generated, if a first final value, which, together with the data, is transmitted as a second, coded sequence of the count, differs from a second final value, which, like the count, is formed from the first, transmitted sequence.

According to another formulation of the present invention, this and other objects are achieved by a mobile data memory and a reader/writer for carrying out the method. Finally, according to yet another formulation of the present invention, this and other objects of the invention are achieved by an identification system having the reader/writer and having at least one mobile data memory.

A simple upward and downward counter allows for quick identification of a data transmission error with a high degree of confidence.

Furthermore, the complexity for driving the upward and downward counter is very low. The counter may be a simple software program or a simple electronic circuit, for example a binary cycle counter, which has a low circuitry complexity.

### BRIEF DESCRIPTION OF THE DRAWINGS

The invention will be explained in more detail with reference to the following figures, in which:

FIG. 1 shows an exemplary embodiment of an identification system, which has a reader/writer and a mobile data memory, each of which having a coding device for carrying out the inventive method for non-contacting interchange of data;

FIG. 2 shows an exemplary embodiment of a coding rule for protected transmission of data according to the invention, whose coding is represented by a sequence of on and off values; and

FIG. 3 shows an exemplary embodiment of the method according to the invention, in which the on values are modulated, on the basis of ISO/IEC Standard 14443, by using Manchester coding and by using an auxiliary carrier in accordance with Type A of the above-mentioned standard.

### DETAILED DESCRIPTION OF THE PREFERRED EMBODIMENTS

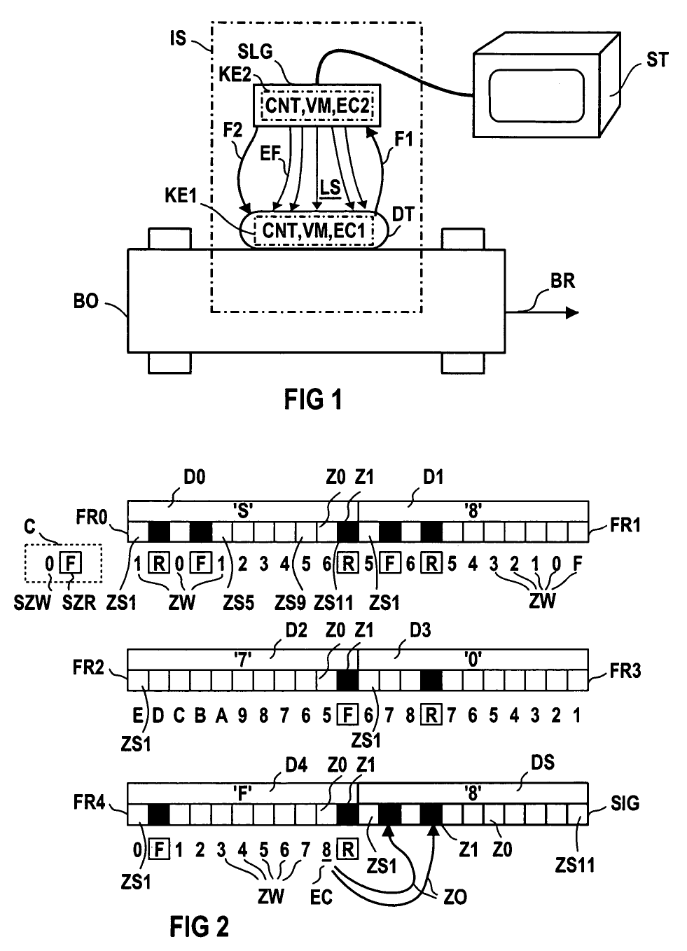

By way of example, FIG. 1 shows an identification system IS, which has a reader/writer SLG and a mobile data memory DT. The reader/writer SLB and the mobile data memory DT have a coding device KE1, KE2, respectively, for carrying out the method according to the invention. The mobile data memory DT is attached to a moving object BO, such as transportation means, which is moving in a movement direction BR relative to the reader/writer SLG. In the exemplary embodiment shown in FIG. 1, data is transmitted via a non-contacting data transmission path LS, for example an air interface. The right-hand upper part of FIG. 1 shows, by way of example, a control computer ST, which is connected to the reader/writer SLG via an interface.

Via this interface, data is interchanged between the control computer ST and the reader/writer SLG, for example for data acquisition purposes. Furthermore, the respective coding devices KE1, KE2 have, by way of example, a cycle counter CNT and a comparison unit VM for carrying out the method according to the invention. If incorrect data transmission is determined, the comparison units VM generate error information F1, F2 for the respective remote station DT, SLG.

In addition, the mobile data memory DT is supplied with power via the air interface LS. Energy flow lines EF are shown in order to illustrate the energy flow from the reader/writer SLG to the mobile data memory DT. The energy may be carried by electrical or magnetic fields, for example.

FIG. 2 shows an exemplary embodiment of a coding rule for protected transmission of data D0-D4. In accordance with the invention, the coding “S”, “0”-“F” of the data D0-D4 is respectively represented by a sequence FR0-FR4 of on and off values Z1, Z0. By way of example, the first data item D0 is a control data item D0, which contains a control command “S”. This command indicates, for example, to the remote station DT, SLG that the data D1-D4, which is awaiting transmission, will follow immediately. The data D1-D4 may be regarded as the actual useful data and may, for example, be bits or data bytes or hexadecimal numbers with numerical values from “0” to “F”, as illustrated in the exemplary embodiment of FIG. 2.

Furthermore, according to the invention, the sequence FR0-FR4 is structured into a sequence of time slot frames FR0-FR4. Therein, a time slot frame FR0-FR4 is coded with the predetermined number of on and off values Z1, Z0, in order to represent a data item D0-D4. Furthermore, according to the invention, the sequence of time slot frames FR0-FR4 is followed by a signature frame SIG that has a corresponding structure and which contains the coded “S”, “0”-“F” sequence SIG. In the exemplary embodiment of FIG. 2, in order to represent the hexadecimal numerical values of the actual useful data D1-D4, a number having the value 16 was predetermined for the coding “0”-“F” of the associated sequence FR1-FR4 of on and off values Z1, Z0. This is illustrated in the exemplary embodiment of FIG. 2, wherein the coding “8” of the data protection block DS is represented by the signature frame SIG.

Furthermore, in the exemplary embodiment of FIG. 2, each time slot frame FR0-FR4 as well as the protection frame is subdivided into 11 time slots ZS1-ZS11.

The above-mentioned coding “S”, “0”-“F” can be produced by appropriate allocation of on and off values Z1, Z0 in these time slots ZS1-ZS11.

As illustrated by dashed lines, FIG. 2 shows a count C, which is preloaded with a start count SZW and with a counting direction F/R.

According to the invention, the count C, which represents the predetermined number, is formed for protected transmission of the data D0-D4 in that the counting direction F, R changes after each on value Z1, and in that the count C is incremented or decremented for each off value Z0. Error information F1, F2 can then be produced, if a first final value EC, which is transmitted, together with the data D0-D4, as a coded “S”, “0”-“F” sequence SIG of the count C, differs from a second final value EC1, EC2. Like the count C, the second final value EC1, EC2 is formed from the transmitted sequence FR0-FR4.

In the exemplary embodiment shown in FIG. 2, the count C has already been preloaded with the start count SZW 0 and with the start counting direction SZR “forward”. In order to assist understanding of the manner in which the count is formed according to the invention, the respective values ZW of the count C and the current counting direction F, R are shown underneath the time slots ZS1-ZS11. In the beginning, the count C is increased to the value 1 by the first time slot ZS1 of the first time slot frame FR0 having the off value Z0.

In the next time slot ZS2, the on value Z1 changes the counting direction F, R to “reverse”. Thus, in the next time slot ZS3 having the off value Z0, the count is decremented to the value 0.

According to the invention, the count C may also assume periodic values ZW, wherein the periodic values ZW may be numerical values in a numerical system. This is illustrated in FIG. 2 for the further count formation. As can be seen, the count C can assume only values ZW in a periodic sequence in the hexadecimal numerical system “0”-“F”. This is possible because, when incremented, the count C overflows from “F” to “0”, or, when it is decremented, underflows in a corresponding manner. Finally, at the end of the count formation process, and in accordance with the previously defined coding “0”-“F”, the first final value EC with the value “8” is written to the time slots ZS1-ZS11 in the protection frame SIG. Thus, in the exemplary embodiment of FIG. 2, the “8”, which is coded into the time slot frame FR1, has the same loading with on and off values Z1, Z0 as the last final value EC, which is formed by the counting process in the protection frame SIG.

This makes it possible to use a simple cycle counter CNT to simulate the respective values ZW of the count C. In the exemplary embodiment of FIG. 2, this can be done, in a simple manner, by means of a binary cycle counter CNT with four significant digits so as to represent 16 possible values ZW. This allows for simple implementation of the method according to the invention in appropriate apparatuses, for example in the mobile data memory DT or in thr reader/writer SLG for carrying out the method.

Advantageously, the cycle counter CNT is a simple software program or a simple electronic circuit, for example the above-mentioned binary cycle counter, which has a low circuitry complexity.

It is a further advantage that any offset in an on value Z1 in the time slot framework or any additional or missing occupancy of the time slots ZS1-ZS11 in a time slot frame FR0-FR4 with an on value Z1 leads to a different final value EC of the count C.

Together with the simple technical implementation of the cycle counter CNT mentioned above, a data transmission error can thus be quickly identified with a high degree of confidence.

Furthermore, according to the invention, all of the on and off values Z1, Z0 to be transmitted can be coded such that an on value Z1 is followed by at least one off value Z0, as is shown in the exemplary embodiment of FIG. 2.

This makes it possible to provide a continuous power supply for the data memory electronics—as described at the outset—in that, for power transmission purposes, the carrier frequency, which is modulated with the data to be transmitted, is switched off only for a maximum time interval. In the present example, the maximum time interval corresponds to the duration of one on value Z1.

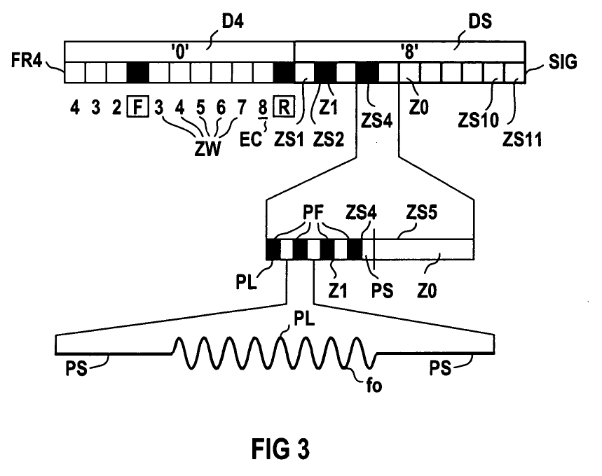

FIG. 3 shows an exemplary embodiment of the method according to the invention, in which the on values Z1 are modulated, on the basis of ISO/IEC Standard 14443, by using Manchester coding and by using an auxiliary carrier in accordance with Type A of the above-mentioned standard.

Furthermore, in accordance with the invention, an on value Z1 may be formed by a pulse sequence PF. The pulse sequence PF may have an even number of pulses PL and pauses PS with the same duty ratio. Furthermore, a pulse PL may be associated with a predetermined number of sinusoidal carrier oscillations fo.

Consequently, the method according to the invention can be used for protected transmission of data in the technically specified context of the above-mentioned standard.

Furthermore, a mobile data memory DT can be used for non-contacting interchange of a sequence of data D0-D4 with a reader/writer SLG. Therein, the mobile data memory DT has a first coding device KE1 for carrying out the method according to the invention. The first coding device KE1 in the mobile data memory DT may have a cycle counter CNT in order to form the count C, and a comparison unit VM for generating a first error message F1, if the first final value EC of the count C differs from the second final value EC1. Therein, the second final value EC1 is formed, in the same way as the count C, from the transmitted sequence FR0-FR4.

A transmission error can thus be indicated to the reader/writer by means of the first error information item F1. The transmission of the most recent data sequence may then be repeated, for example.

In analogous manner, the reader/writer SLG is used for non-contacting interchange of a sequence of data D0-D4 with at least one mobile data memory DT. Therein, the reader/writer SLG has a second coding device KE2 for carrying out the method according to the invention. The second coding device KE2 in the reader/writer SLG may have a cycle counter CNT for forming the count C and a comparison unit VM for generating a second error information item F2, if the first final value EC of the count C differs from the second final value EC2. Therein, the second final value EC2 is formed, in the same way as the count C, from the transmitted sequence FR0-FR4.

A transmission error can thus be indicated to the mobile reader/writer DT by means of the second error information item F2. The transmission of the most recent data sequence may then be repeated, for example.

Finally, the method according to the invention can be carried out by operating an identification system IS, which uses a modulation method based on ISO/IEC Standard 14443 or ISO/IEC Standard 15693 in an ISM frequency band, in particular in an ISM frequency band at 13.56 MHz. Furthermore, via a non-contacting data transmission path LS, the identification system IS can be used to interchange sequences of data D1-D4 between at least one reader/writer SLG and at least one mobile data memory DT.

This is particularly advantageous for an air interface LS that couples the reader/writer SLG and the mobile data memory DT in an inductive manner.

The above description of the preferred embodiments has been given by way of example. From the disclosure given, those skilled in the art will not only understand the present invention and its attendant advantages, but will also find apparent various changes and modifications to the structures and methods disclosed. It is sought, therefore, to cover all such changes and modifications as fall within the spirit and scope of the invention, as defined by the appended claims, and equivalents thereof.

What is claimed is:

1. A method for protected transmission of data whose coding is represented by a first, transmitted sequence having a predetermined number of on and off values, comprising:
forming a count, which represents the predetermined number, by changing a counting direction after each on-value and by incrementing or decrementing the count for each off-value; and
generating error information, if a first final value, which, together with the data, is transmitted as a second, coded sequence of the count, differs from a second final value, which, like the count, is formed from the first, transmitted sequence.

2. The method as claimed in claim 1, wherein the first, transmitted sequence is structured in a sequence of time slot frames.

3. The method as claimed in claim 2, wherein a time slot frame representing a data item is coded by the predetermined number of on and off values.

4. The method as claimed in claim 2, wherein the sequence of time slot frames is followed by a respectively structured signature frame, which includes the coded sequence of the count.

5. The method as claimed in claim 1, wherein the count assumes periodic values.

6. The method as claimed in claim 5, wherein the periodic values of the count are numerical values in a numerical system.

7. The method as claimed in claim 1, wherein the coding of all the on and off values to be transmitted is carried out in a manner that an on-value is followed by at least one off-value.

8. The method as claimed in claim 1, wherein an on-value is formed by a pulse sequence.

9. The method as claimed in claim 8, wherein the pulse sequence has an even number of pulses and pauses with a same duty ratio.

10. The method as claimed in claim 9, wherein a pulse is associated with a predetermined number of carrier oscillations.

11. A mobile data memory for non-contacting interchange of a sequence of data items with a reader/writer, the mobile data memory comprising a first coding device configured
(a) to transmit data whose coding is represented by a first, transmitted sequence having a predetermined number of on and off values;
(b) to form a count, which represents the predetermined number of on and off values, by changing a counting direction after each on-value and by incrementing or decrementing the count for each off-value; and
(c) to generate error information, if a first final value, which, together with the data, is transmitted as a second, coded sequence of the count, differs from a second final value, which, like the count, is formed from the first, transmitted sequence.

12. The mobile data memory as claimed in claim 11, wherein the first coding device comprises:
a cycle counter for forming the count; and
a comparison unit for generating a first error message, if the first final value of the count differs from the second final value.

13. A reader/writer for non-contacting interchange of a sequence of data items with a mobile data memory, the reader/writer comprising a second coding device configured
(a) to transmit data whose coding is represented by a first, transmitted sequence having a predetermined number of on and off values;
(b) to form a count, which represents the predetermined number of on and off values, by changing a counting direction after each on-value and by incrementing or decrementing the count for each off-value; and
(c) to generate error information, if a first final value, which, together with the data, is transmitted as a second, coded sequence of the count, differs from a second final value, which, like the count, is formed from the first, transmitted sequence.

14. The reader/writer as claimed in claim 13, wherein the second coding device comprises
a cycle counter for forming the count; and
a comparison unit for generating a second error message, if the first final value of the count differs from the second final value.

15. An identification system, comprising
at least one mobile data memory; and
a reader/writer;
wherein the mobile data memory and the reader/writer interchange sequences of data via a non-contacting data transmission path;
wherein a coding of the data is represented by a first, transmitted sequence having a predetermined number of on and off values; and
wherein at least one of the mobile data memory and the reader/writer comprises:
a cycle counter configured to form a count, which represents the predetermined number of on and off values, by changing a counting direction after each on-value and by incrementing or decrementing the count for each off-value; and
a comparison unit to generate error information, if a first final value, which, together with the data, is transmitted as a second, coded sequence of the count, differs from a second final value, which, like the count, is formed from the first, transmitted sequence.

16. The identification system as claimed in claim 15, wherein the identification system is configured to operate in an ISM frequency band on the basis of the ISO/IEC 1443 standard.

17. The identification system as claimed in claim 15, wherein the identification system is configured to operate in an ISM frequency band on the basis of the ISO/IEC 15693 standard.

18. The identification system as claimed in claim 16, wherein the ISM frequency band comprises a 13.56 MHz frequency band.

19. The identification system as claimed in claim 17, wherein the ISM frequency band comprises a 13.56 MHz frequency band.
